(19) United States
(12) Patent Application Publication
(10) Pub. No.: US 2026/0362877 A1
(43) Pub. Date: Nov. 12, 2026

(54) Display Device Including Light Emitting Diode and Method of Fabricating the Same

(71) Applicant: LG Display Co., Ltd., Seoul (KR)

(72) Inventors: Ho-Jin Ryu, Paju-si (KR); Heume-Il Baek, Paju-si (KR)

(21) Appl. No.: 19/575,272

(22) Filed: Mar. 23, 2026

(30) Foreign Application Priority Data
May 7, 2025 (KR) 10-2025-0058967

(51) Int. Cl. H10H 29/41; H10H 29/01; H10H 29/49; H10H 29/80; H10K 59/12; H10K 59/124; H10K 59/131

(52) U.S. Cl. CPC H10H 29/41; H10H 29/012; H10H 29/49; H10H 29/8325; H10K 59/1201; H10K 59/124; H10K 59/131

(57) ABSTRACT

A display device presented herein includes a substrate, a low level power line on the substrate, a transistor on the low level power line, a first planarizing layer on the transistor, first and second reflecting electrodes on the first planarizing layer, an adhesive layer on the first and second reflecting electrodes, first and second light emitting diodes on the adhesive layer, first, second and third connecting electrodes on the adhesive layer, a second planarizing layer on the first and second light emitting diodes and on the first, second and third connecting electrodes, and fourth and fifth connecting electrodes on the second planarizing layer.

### CROSS-REFERENCE TO RELATED APPLICATION

The present application claims priority to Republic of Korea Patent Application No. 10-2025-0058967, filed on May. 7, 2025, which is hereby incorporated by reference in its entirety.

### FIELD

The present disclosure relates to a display device, and more particularly, to a display device including a light emitting diode where a detection capability is improved and a deteriorated subpixel is repaired due to a bridge pattern.

### BACKGROUND

Recently, various flat panel display devices such as a liquid crystal display device (LCD), an organic light emitting diode (OLED) display device and a field emission display (FED) device having excellent properties of a thin profile, a light weight and a low power consumption have been developed and applied to various fields.

Although the OLED display device among the various flat panel display devices has an advantage such that an additional light source is not required, the OLED display device has a disadvantage such that deterioration may occur by an external circumstance due to a property of an organic material vulnerable to moisture and oxygen.

To overcome the disadvantage, a display device using a light emitting diode (LED) (or a light emitting diode (LED) chip) of an inorganic material has been suggested. In the display device including a light emitting diode, two light emitting diode chips in series may be disposed in one subpixel for a relatively high luminance and a relatively low power consumption.

In the display device including a light emitting diode, after two light emitting diode chips are transferred to each subpixel, a lighting test is performed by applying a voltage to first and second chip electrodes of the light emitting diode using a probe. Since the first chip electrode of one of two light emitting diode chips in series has a floating state, it is impossible to perform a lighting test for one of two light emitting diode chips without an additional process.

Further, when one of two light emitting diode chips in series is deteriorated, the other of two light emitting diode chips also does not emit a light. As a result, the whole corresponding subpixel is deteriorated.

In addition, since an additional process such as a laser welding is required for emission of the other of two light emitting diode chips, a limitation is generated in design and process.

### SUMMARY

Accordingly, the present disclosure is directed to a display device that substantially obviates one or more of the problems due to limitations and disadvantages of the related art.

More specifically, the present disclosure is to provide a display device including a light emitting diode where a detection capability of a lighting test for first and second light emitting diode chips in series and a production yield are improved and a fabrication process is improved by performing a lighting test using first and second connecting electrodes connected through a first bridge pattern and then removing the first bridge pattern and a method of fabricating the display device.

In addition, the present disclosure is to provide a display device including a light emitting diode where a subpixel including first and second light emitting diode chips is repaired and a production yield is improved by maintaining a bridge pattern between first and second connecting electrodes or forming a second bridge pattern between fourth and fifth connecting electrodes and a method of fabricating the display device.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a substrate; a low level power line on the substrate; a transistor on the low level power line; a first planarizing layer on the transistor; first and second reflecting electrodes on the first planarizing layer, the first and second reflecting electrodes spaced apart from each other and connected to the transistor and the low level power line, respectively; an adhesive layer on the first and second reflecting electrodes; first and second light emitting diodes on the adhesive layer, the first and second light emitting diodes spaced apart from each other; first, second and third connecting electrodes on the adhesive layer, the second connecting electrode connected to the second reflecting electrode, and the third connecting electrode spaced apart from the first connecting electrode and connected to the first reflecting electrode; a second planarizing layer on the first and second light emitting diodes and the first, second and third connecting electrodes; and fourth and fifth connecting electrodes on the second planarizing layer, the fourth and fifth connecting electrodes spaced apart from each other and connected to the first and second light emitting diodes, respectively.

In one or more other embodiments, a method of fabricating a display device includes: forming a low level power line on a substrate; forming a transistor on the low level power line; forming a first planarizing layer on the transistor; forming first and second reflecting electrodes on the first planarizing layer, the first and second reflecting electrodes spaced apart from each other and connected to the transistor and the low level power line, respectively; forming an adhesive layer on the first and second reflecting electrodes; forming first and second light emitting diodes on the adhesive layer, the first and second light emitting diodes spaced apart from each other; forming first, second and third connecting electrodes and a first bridge pattern on the adhesive layer, the second connecting electrode connected to the second reflecting electrode, the third connecting electrode spaced apart from the first connecting electrode and connected to the first reflecting electrode, and the first bridge pattern connecting the first and second connecting electrodes; forming a second planarizing layer on the first and second light emitting diodes, the first, second and third connecting electrodes and the first bridge pattern; and forming fourth and fifth connecting electrodes on the second planarizing layer, the fourth and fifth connecting electrodes connected to the first and second light emitting diodes, respectively.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this disclosure, illustrate embodiments of the disclosure and together with the description serve to explain the principles of the disclosure.

In the drawings:

FIG. 1 is a view showing a display device according to a first embodiment of the present disclosure.

FIG. 2 is a view showing a subpixel of a display device according to a first embodiment of the present disclosure.

FIG. 3 is a plan view showing a subpixel having normal first and second light emitting diodes of a display panel of a display device according to a first embodiment of the present disclosure.

FIG. 4 is a cross-sectional view taken along a line IV-IV of FIG. 3.

FIG. 5 is a plan view showing a subpixel having a normal first light emitting diode and an abnormal second light emitting diode of a display panel of a display device according to a first embodiment of the present disclosure.

FIG. 6 is a cross-sectional view taken along a line VI-VI of FIG. 5.

FIG. 7 is a plan view showing a subpixel having an abnormal first light emitting diode and a normal second light emitting diode of a display panel of a display device according to a first embodiment of the present disclosure.

FIG. 8 is a cross-sectional view taken along a line VIII-VIII of FIG. 7.

FIGS. 9A-9D are plan views showing a method of fabricating a subpixel having normal first and second light emitting diodes of a display panel of a display device according to a first embodiment of the present disclosure.

FIGS. 10A-10D are cross-sectional views showing a method of fabricating a subpixel having normal first and second light emitting diodes of a display panel of a display device according to a first embodiment of the present disclosure.

FIGS. 11A-11D are plan views showing a method of fabricating a subpixel having a normal first light emitting diode and an abnormal second light emitting diode of a display panel of a display device according to a first embodiment of the present disclosure.

FIGS. 12A-12D are cross-sectional views showing a method of fabricating a subpixel having a normal first light emitting diode and an abnormal second light emitting diode of a display panel of a display device according to a first embodiment of the present disclosure.

FIGS. 13A-13D are plan views showing a method of fabricating a subpixel having an abnormal first light emitting diode and a normal second light emitting diode of a display panel of a display device according to a first embodiment of the present disclosure.

FIGS. 14A-14D are cross-sectional views showing a method of fabricating a subpixel having an abnormal first light emitting diode and a normal second light emitting diode of a display panel of a display device according to a first embodiment of the present disclosure.

FIG. 15 is a plan view showing a subpixel having a normal light emitting diode and an abnormal light emitting diode of a display panel of a display device according to a second embodiment of the present disclosure.

FIG. 16 is a cross-sectional view taken along a line XVI-XVI of FIG. 15.

FIGS. 17A-17D are plan views showing a method of fabricating a subpixel having a normal light emitting diode and an abnormal light emitting diode of a display panel of a display device according to a second embodiment of the present disclosure.

FIGS. 18A-18D are cross-sectional views showing a method of fabricating a subpixel having a normal light emitting diode and an abnormal light emitting diode of a display panel of a display device according to a second embodiment of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure may be sufficiently thorough and complete to assist those skilled in the art to fully understand the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the disclosure, unless otherwise specified.

In the following description, where the detailed description of the relevant known function or configuration may unnecessarily obscure a feature or embodiment of the present disclosure, a detailed description of such known function or configuration may be omitted or a brief description may be provided.

Where the terms "comprise," "have," "include," and the like are used, one or more other elements may be added unless the term, such as "only," is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using "on," "over," "under," "above," "below," "beside," "next," or the like, one or more other parts may be located between the two parts unless a more limiting term, such as "immediate(ly)," "direct(ly)," or "close(ly)" is used. For example, where an element or layer is disposed "on" another element or layer, a third layer or element may be interposed therebetween.

Although the terms "first," "second," A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

As used herein, the terms "connected" and "coupled" are intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" should be interpreted in the same manner.

The term "at least one" should be understood to include all combinations of one or more of related elements. For example, the term of "at least one of first, second and third elements" may include all combinations of two or more of the first, second and third elements as well as the first, second or third element.

The term "display device" may include a display device in a narrow sense such as liquid crystal module (LCM), an organic light emitting diode (OLED) module and a quantum dot (QD) module including a display panel and a driving unit for driving the display panel. In addition, the term "display device" may include a complete product (or a final product) including the LCM, the OLED module or the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module or the QD module as well as a display device in a narrow sense such as the LCM, the OLED module or the QD module.

According to circumstances, the LCM, the OLED module or the QD module having a display panel and a driving unit may be expressed as "a display device", and an electronic apparatus of a complete product including the LCM, the OLED module or the QD module may be expressed as "a set device." For example, a display device in a narrow sense may include a display panel of a liquid crystal, an organic light emitting diode or a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of moisture or oxygen into the emitting element layer. In addition, the emitting element layer on the array may include an inorganic light emitting layer, for example, a nano-sized material layer or a quantum dot.

The thin film transistor of the present disclosure may include one of an oxide thin film transistor, an amorphous silicon thin film transistor, and a low temperature polycrystalline silicon thin film transistor.

Features of various embodiments of the present disclosure may be partially or entirely coupled to or combined with each other. They may be linked and operated technically in various ways as those skilled in the art may sufficiently understand. The embodiments may be carried out independently of or in association with each other in various combinations.

Hereinafter, a display device according to various embodiments of the present disclosure will be described in detail with reference to the accompanying drawings.

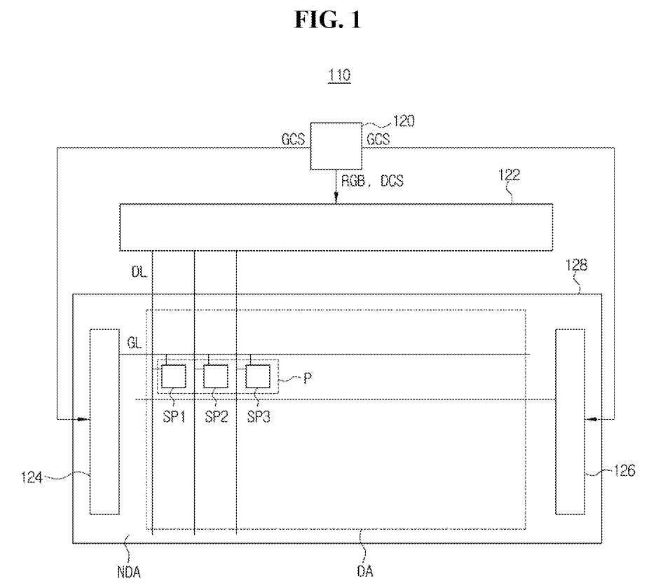

FIG. 1 is a view showing a display device according to a first embodiment of the present disclosure. Although the display device may be an organic light emitting diode (OLED) display device, it is not limited thereto. For example, the display device may be a quantum dot display device, a micro light emitting diode (LED) display device or a mini light emitting diode (LED) display device.

In FIG. 1, a display device 110 according to a first embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal DCS and a gate control signal GCS using an image signal and a plurality of timing signals including a data enable signal, a horizontal synchronization signal, a vertical synchronization signal and a clock signal transmitted from an external system such as a graphic card or a television system.

The timing controlling unit 120 transmits the image data RGB and the data control signal DCS to the data driving unit 122, and transmits the gate control signal GCS to the first and second gate driving units 124 and 126.

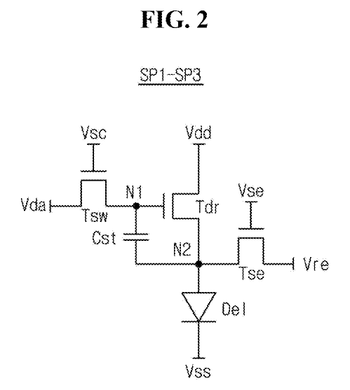

The data driving unit 122 generates a data signal (a data voltage) Vda (of FIG. 2) using the image data RGB and the data control signal DCS transmitted from the timing controlling unit 120 and transmits the data signal Vda to a data line DL of the display panel 128.

The first and second gate driving units 124 and 126 generate a gate signal (a gate voltage) Vsc and Vse (of FIG. 2) using the gate control signal GCS transmitted from the timing controlling unit 120 and applies the gate signal Vsc and Vse to a gate line GL of the display panel 128.

The first and second gate driving units 124 and 126 may have a gate in panel (GIP) type to be formed in a non-display area NDA of a substrate of the display panel 128 having the gate line GL, the data line DL and a pixel P.

Although the first and second gate driving units 124 and 126 are disposed in both side portions of the display panel 128 in the first embodiment of FIG. 1, one gate driving unit may be disposed in one side portion of the display panel 128 in another embodiment.

The display panel 128 includes a display area DA at a central portion thereof and a non-display area NDA surrounding the display area DA. The display panel 128 displays an image using the gate signal Vsc and Vse and the data signal Vda. Hereinafter, the gate signal Vsc and Vse may be referred to as the scan signal Vsc and sensing signal Vse.

For displaying an image, the display panel 128 includes a plurality of pixels P, a plurality of gate lines GL and a plurality of data lines DL in the display area DA.

Each of the plurality of pixels P includes first, second and third subpixels SP1, SP2 and SP3, and the gate line GL and the data line DL cross each other to define the first, second and third subpixels SP1, SP2 and SP3. Each of the first, second and third subpixels SP1, SP2 and SP3 is connected to the gate line GL and the data line DL. For example, the first, second and third subpixels SP1, SP2 and SP3 may correspond to red, green and blue colors, respectively.

In one or more other embodiments, each of the plurality of pixels P includes first, second, third and fourth subpixels SP1, SP2, SP3 and SP4 corresponding to red, green, blue and white colors, respectively.

Each of the first, second and third subpixels SP1, SP2 and SP3 may include a plurality of transistors such as a switching transistor Tsw (of FIG. 2), a driving transistor Tdr (of FIG. 2) and a sensing transistor Tse (of FIG. 2), a storage capacitor Cst (of FIG. 2) and a light emitting diode Del (of FIG. 2).

FIG. 2 is a view showing a subpixel of a display device according to a first embodiment of the present disclosure.

In FIG. 2, each of the first, second and third subpixels SP1, SP2 and SP3 of the display device 110 according to a first embodiment of the present disclosure includes a switching transistor Tsw, a driving transistor Tdr, a sensing transistor Tse, a storage capacitor Cst and a light emitting diode Del.

Although each of the first, second and third subpixels SP1, SP2 and SP3 has a 3T1C structure having three transistors and one storage capacitor in the first embodiment of FIG. 2, each of the first, second and third subpixels SP1, SP2 and SP3 may have one of a 6T1C structure having six transistors and one storage capacitor, a 7T1C structure having seven transistors and one storage capacitor and a 8T1C structure having eight transistors and one storage capacitor in another embodiment.

Although the switching transistor Tsw, the driving transistor Tdr and the sensing transistor Tse may have a negative type (N type) in the first embodiment of FIG. 2, at least one of the switching transistor Tsw, the driving transistor Tdr and the sensing transistor Tse may have a positive type (P type) in another embodiment.

The switching transistor Tsw is switched according to a scan signal Vsc to transmit a data signal Vda to a first node N1.

A gate electrode of the switching transistor Tsw is connected to the gate line GL to receive the scan signal Vsc, a drain electrode of the switching transistor Tsw is connected to the data line DL to receive the data signal Vda, and a source electrode of the switching transistor Tsw is connected to the first node N1.

The driving transistor Tdr is switched according to a voltage of the first node N1 to transmit a high level signal (high level voltage) Vdd to a second node N2.

A gate electrode of the driving transistor Tdr is connected to the first node N1, a drain electrode of the driving transistor Tdr is connected to a high level power line to receive the high level signal Vdd, and a source electrode of the driving transistor Tdr is connected to the second node N2.

The sensing transistor Tse is switched according to a sensing signal (sensing voltage) Vse to transmit a reference signal (reference voltage) Vre to the second node N2 or transmit a voltage of the second node N2 to a reference line.

A gate electrode of the sensing transistor Tse is connected to the gate line GL to receive the sensing signal Vse, a drain electrode of the sensing transistor Tse is connected to the reference line to receive the reference signal Vre or transmit a voltage of the second node N2 to the reference line, and a source electrode of the sensing transistor Tse is connected to the second node N2.

The storage capacitor Cst keeps the data signal Vda supplied to the first node N1 for one frame and stores a threshold voltage Vth of the driving transistor Tdr.

A first capacitor electrode of the storage capacitor Cst is connected to the first node N1, and a second capacitor electrode of the storage capacitor Cst is connected to the second node N2.

The light emitting diode Del emits a light of a luminance proportional to a current of the driving transistor Tdr.

An anode of the light emitting diode Del is connected to the second node N2, and a cathode of the light emitting diode Del is connected to a low level power line to receive a low level signal (low level voltage) Vss.

The source electrode of the switching transistor Tsw, the gate electrode of the driving transistor Tdr and the first capacitor electrode of the storage capacitor Cst constitute the first node N1, and the source electrode of the driving transistor Tdr, the source electrode of the sensing transistor Tse, the second capacitor electrode of the storage capacitor Cst and the anode of the light emitting diode Del constitute the second node N2.

The light emitting diode Del may display an image having a luminance corresponding to the image data RGB according to a driving of subpixel circuits of the first, second and third subpixels SP1, SP2 and SP3.

A planar structure and a cross-sectional structure of each of the first, second and third subpixels SP1, SP2 and SP3 of the display panel 128 of the display device 110 will be illustrated with reference to drawings.

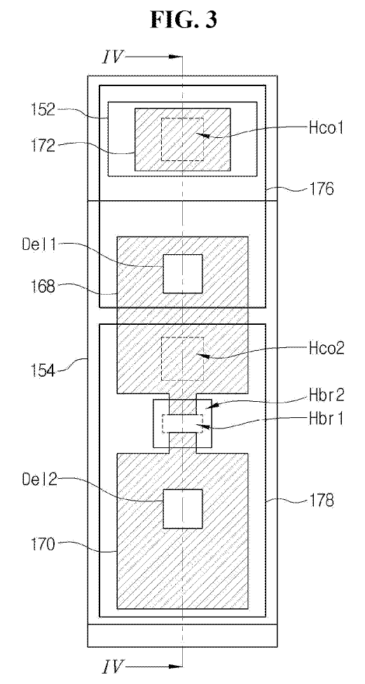

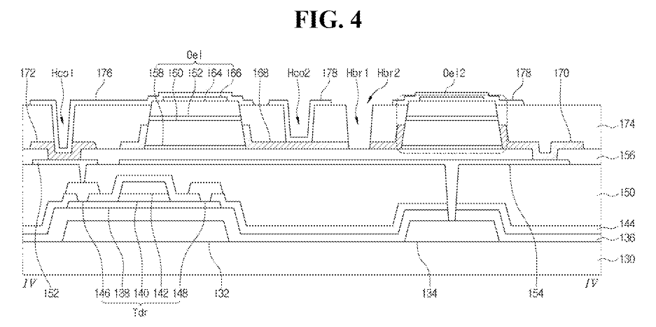

FIG. 3 is a plan view showing a subpixel having normal first and second light emitting diodes of a display panel of a display device according to a first embodiment of the present disclosure, and FIG. 4 is a cross-sectional view taken along a line IV-IV of FIG. 3.

In FIGS. 3 and 4, a light shielding pattern 132 and the low level power line 134 are disposed in each of the first, second and third subpixels SP1, SP2 and SP3 on a substrate 130, and a buffer layer 136 is disposed on the light shielding pattern 132 and the low level power line 134 over the entire substrate 130.

The light shielding pattern 132 may block a light incident from a lower portion of the substrate 130, and the low level power line 134 may supply the low level signal Vss.

The light shielding pattern 132 and the low level power line 134 may include the same material in the same layer as each other.

For example, the light shielding pattern 132 and the low level power line 134 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

The buffer layer 136 may block moisture or oxygen permeating from an exterior.

For example, the buffer layer 136 may have a single layer or a multiple layer of an inorganic insulating material such as silicon oxide (SiO2) and silicon nitride (SiNx).

A semiconductor layer 138 is disposed on the buffer layer 136 corresponding to the light shielding pattern 132, and a gate insulating layer 140 is disposed on a central portion of the semiconductor layer 138.

The semiconductor layer 138 includes a channel region not doped with an impurity at a central portion thereof and source and drain regions doped with an impurity at both side portions of the channel region.

For example, the semiconductor layer 138 may include a polycrystalline semiconductor material such as polycrystalline silicon or an oxide semiconductor material such as indium gallium zinc oxide (IGZO), zinc oxide (ZnO), tin oxide (SnO2), copper oxide (Cu2O), nickel oxide (NiO), indium tin zinc oxide (ITZO) and indium aluminum zinc oxide (IAZO).

For example, the gate insulating layer 140 may have a single layer or a multiple layer of an inorganic insulating material such as silicon oxide (SiO2) and silicon nitride (SiNx).

A gate electrode 142 is disposed on the gate insulating layer 140 corresponding to the channel region of the semiconductor layer 138, and an interlayer insulating layer 144 is disposed on the gate electrode 142 over the entire substrate 130.

For example, the gate electrode 142 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

For example, the interlayer insulating layer 144 may have a single layer or a multiple layer of an inorganic insulating material such as silicon oxide (SiO2) and silicon nitride (SiNx).

A source electrode 146 and a drain electrode 148 spaced apart from each other are disposed on the interlayer insulating layer 144, and a first planarizing layer 150 is disposed on the source electrode 146 and the drain electrode 148 over the entire substrate 130.

The source electrode 146 and the drain electrode 148 are connected to the source region and the drain region, respectively, of the semiconductor layer 138 through contact holes in the interlayer insulating layer 144.

Although not shown, the drain electrode 148 may be connected to the light shielding pattern 132 through a contact hole in the interlayer insulating layer 144 and the buffer layer 136.

The source electrode 146 and the drain electrode 148 may include the same material in the same layer as each other.

For example, the source electrode 146 and the drain electrode 148 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

For example, the first planarizing layer 150 may have a single layer or a multiple layer of an organic insulating material such as photoacryl and benzocyclobutene (BCB).

The semiconductor layer 138, the gate electrode 142, the source electrode 146 and the drain electrode 148 may constitute the driving transistor Tdr.

Although not shown, the first capacitor electrode and the second capacitor electrode may be disposed in each of the first, second and third subpixels SP1, SP2 and SP3. The first capacitor electrode may include the same material in the same layer as the gate electrode 142, and the second capacitor electrode may include the same material in the same layer as the source electrode 146 and the drain electrode 148. The first capacitor electrode, the interlayer insulating layer 144 and the second capacitor electrode may constitute the storage capacitor Cst.

First and second reflecting electrodes 152 and 154 spaced apart from each other are disposed on the first planarizing layer 150, and an adhesive layer 156 is disposed on the first and second reflecting electrodes 152 and 154 over the entire substrate 130.

The first reflecting electrode 152 is connected to the source electrode 146 through a contact hole in the first planarizing layer 150, and the second reflecting electrode 154 is connected to the low level power line 134 through a contact hole in the first planarizing layer 150, the interlayer insulating layer 144 and the buffer layer 136.

The first and second reflecting electrodes 152 and 154 may include the same material in the same layer as each other and may include a metallic material having an excellent reflectance property.

For example, the first and second reflecting electrodes 152 and 154 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

The adhesive layer 156 has contact holes exposing the first and second reflecting electrodes 152 and 154, respectively.

For example, the adhesive layer 156 may include an organic insulating material such as an epoxy resin and may have a thickness of about 1.5μm to about 2.5μm.

First and second light emitting diodes (chips) Del1 and Del2 spaced apart from each other and first, second and third connecting electrodes 168, 170 and 172 spaced apart from each other are disposed in each of the first, second and third subpixels SP1, SP2 and SP3 on the adhesive layer 156.

Each of the first and second light emitting diode Del1 and Del2 as a vertical type light emitting diode chip includes a first chip electrode 158, a first chip semiconductor layer 160, a chip active layer 162, a second chip semiconductor layer 164 and a second chip electrode 166 sequentially on the adhesive layer 156.

The first chip semiconductor layer 160 supplies an electron of the first chip electrode 158 to the chip active layer 162, and the second chip semiconductor layer 164 supplies a hole of the second chip electrode 166 to the chip active layer 162. The chip active layer 162 may generate a light using the electron and the hole.

For example, the first chip electrode 158 may be a cathode and may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

For example, the first chip semiconductor layer 160 may include a negative type gallium nitride (n-GaN), and the second chip semiconductor layer 164 may include a positive type gallium nitride (p-GaN). The chip active layer 162 may include a multi quantum well (MQW).

For example, the second chip electrode 166 may be an anode and may include a transparent conductive material such as indium tin oxide (ITO) and indium zinc oxide (IZO).

Here, each of the first and second light emitting diodes Del1 and Del2 may be a light emitting diode chip which operates normally.

The first connecting electrode 168 is disposed at a periphery of the first light emitting diode Del1 and is connected to a side surface of the first chip electrode 158 of the first light emitting diode Del1.

The second connecting electrode 170 is disposed at a periphery of the second light emitting diode Del2 and is connected to a side surface of the first chip electrode of the second light emitting diode Del2. The second connecting electrode 170 is connected to the second reflecting electrode 154 through a contact hole in the adhesive layer 156.

Since the first and second connecting electrodes 168 and 172 are connected to the first and second light emitting diodes Del1 and Del2, respectively, through a side contact type due to a self-alignment, an efficiency of space utilization is improved.

The third connecting electrode 172 is connected to the first reflecting electrode 152 through a contact hole in the adhesive layer 156.

The first, second and third connecting electrodes 168, 170 and 172 may have one of a polygonal shape such as a rectangular shape, a circular shape and an elliptical shape in a plan view and may have the same material in the same layer as each other.

For example, the first, second and third connecting electrodes 168, 170 and 172 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

A second planarizing layer 174 is disposed on the first and second light emitting diodes Del1 and Del2 and the first, second and third connecting electrodes 168, 170 and 172 over the entire substrate 130, and fourth and fifth connecting electrodes 176 and 178 are disposed on the second planarizing layer 174 corresponding to the first and second light emitting diodes Del1 and Del2.

The second planarizing layer 174 has a first contact hole Hco1 exposing the third connecting electrode 172, a second contact hole Hco2 exposing the first connecting electrode 168 and a first bridge hole Hbr1 exposing the adhesive layer 156 between the first and second connecting electrodes 168 and 170.

A part of the second chip semiconductor layer 164 of each of the first and second light emitting diodes Del1 and Del2 and the second chip electrode 168 are exposed through the second planarizing layer 174.

For example, the second planarizing layer 174 may have a single layer or a multiple layer of an organic insulating material such as photoacryl and benzocyclobutene (BCB), and each of the first and second contact holes Hco1 and Hco2 and the first bridge hole Hbr1 may have a circular shape or a rectangular shape in a plan view.

Although not shown, an end portion of the first connecting electrode 168 and an end portion of the second connecting electrode 170 may be spaced apart from each other by a first width in a region between the first and second connecting electrodes 168 and 170, and the first bridge hole Hbr1 may have a second width smaller than the first width. As a result, each of the first and second connecting electrodes 168 and 170 may have an undercut shape where an end portion of each of the first and second connecting electrodes 168 and 170 is disposed inside an end portion of the second planarizing layer 174 of the first bridge hole Hbr1.

The fourth connecting electrode 176 is connected to the third connecting electrode 172 through the first contact hole Hco1 and is connected to the second chip electrode 166 of the first light emitting diode Del1 exposed through the second planarizing layer 174.

The fifth connecting electrode 178 is connected to the first connecting electrode 168 through the second contact hole Hco2 and is connected to the second chip electrode of the second light emitting diode Del2 exposed through the second planarizing layer 174. The fifth connecting electrode 178 has a second bridge hole Hbr2 exposing the first bridge hole Hbr1.

Each of the fourth and fifth connecting electrodes 176 and 178 may have one of a polygonal shape such as a rectangular shape, a circular shape and an elliptical shape in a plan view and may have the same material in the same layer as each other.

For example, each of the fourth and fifth connecting electrodes 176 and 178 may include a metallic material such as molybdenum (Mo), aluminum (Al), chromium (Cr), gold (Au), titanium (Ti), nickel (Ni), neodymium (Nd) and copper (Cu) or a transparent conductive material such as indium tin oxide (ITO) and indium zinc oxide (IZO). The second bridge hole Hbr2 may have a circular shape or a rectangular shape in a plan veiw.

The second bridge hole Hbr2 may have a third width greater than the second width of the first bridge hole Hbr1.

In the display device 110, since the first chip electrode 158 of the first light emitting diode Del1 and the second chip electrode of the second light emitting diode Del2 are connected to each other through the first connecting electrode 168 and the fifth connecting electrode 178, the first and second light emitting diodes Del1 and Del2 are connected to each other in series between the fourth connecting electrode 176 and the second connecting electrode 170.

As a result, the first light emitting diode Del1 which operates normally may receive a hole from the driving transistor Tdr through the first reflecting electrode 152, the third connecting electrode 172 and the fourth connecting electrode 176 and may receive an electron from the low level power line 134 through the second reflecting electrode 154, the second connecting electrode 170, the second light emitting diode Del2, the fifth connecting electrode 178 and the first connecting electrode 168 to emit a light. The second light emitting diode Del2 which operates normally may receive a hole from the driving transistor Tdr through the first reflecting electrode 152, the third connecting electrode 172, the fourth connecting electrode 176, the first light emitting diode Del1, the first connecting electrode 168 and the fifth connecting electrode 178 and may receive an electron from the low level power line 134 through the second reflecting electrode 154 and the second connecting electrode 170 to emit a light.

Although not shown, an additional planarizing layer or an encapsulating layer may be further disposed on the fourth and fifth connecting electrodes 176 and 178 over the entire substrate 130 for preventing a permeation of oxygen or moisture.

In the display device 110 according to a first embodiment of the present disclosure, when the first and second light emitting diodes Del1 and Del2 operate normally, the first and second light emitting diodes Del1 and Del2 are connected in series between the fourth connecting electrode 176 and the second connecting electrode 170. As a result, a luminance is improved and a power consumption is reduced.

When one of the first and second light emitting diodes Del1 and Del2 operates abnormally, the corresponding subpixel may be repaired using the first and second bridge patterns.

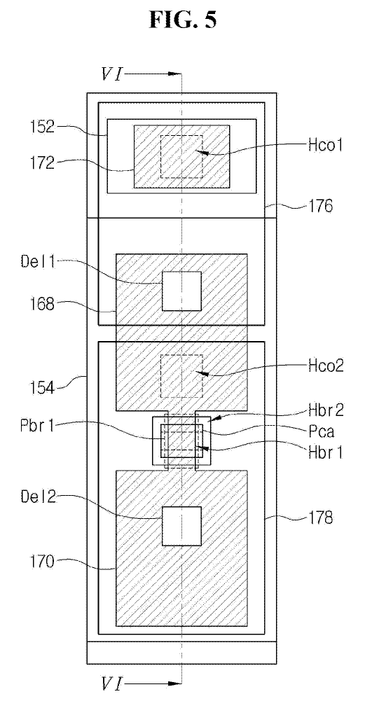

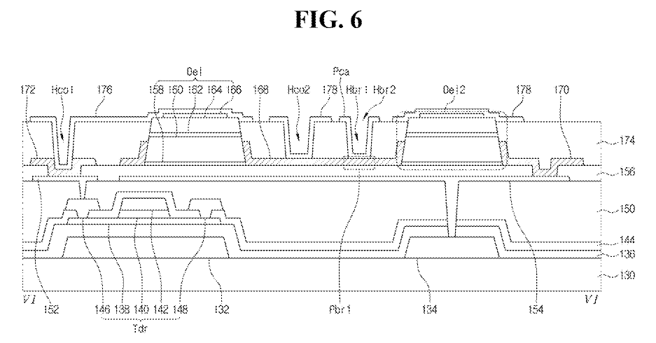

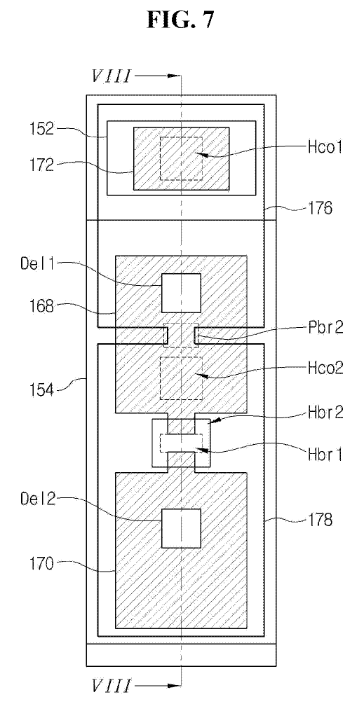

FIG. 5 is a plan view showing a subpixel having a normal first light emitting diode and an abnormal second light emitting diode of a display panel of a display device according to a first embodiment of the present disclosure, and FIG. 6 is a cross-sectional view taken along a line VI-VI of FIG. 5. FIG. 7 is a plan view showing a subpixel having an abnormal first light emitting diode and a normal second light emitting diode of a display panel of a display device according to a first embodiment of the present disclosure, and FIG. 8 is a cross-sectional view taken along a line VIII-VIII of FIG. 7. Illustration on a part the same as that of FIGS. 3 and 4 may be omitted.

In FIGS. 5 and 6, the light shielding pattern 132 and the low level power line 134, the buffer layer 136, the semiconductor layer 138, the gate insulating layer 140, the gate electrode 142, the interlayer insulating layer 144, the source electrode 146 and the drain electrode 148, the first planarizing layer 150, the first and second reflecting electrodes 152 and 154 and the adhesive layer 156 are sequentially disposed on the substrate 130.

The first and second light emitting diodes (chips) Del1 and Del2 spaced apart from each other, the first and second connecting electrodes 168 and 170, a first bridge pattern Pbr1 connecting the first and second connecting electrodes 168 and 170 and the third connecting electrode 172 are disposed in each of the first, second and third subpixels SP1, SP2 and SP3 on the adhesive layer 156.

Here, the first light emitting diode Del1 may be a light emitting diode chip which operates normally, and the second light emitting diode Del2 may be a light emitting diode chip which operates abnormally.

The first connecting electrode 168 is disposed at a periphery of the first light emitting diode Del1 and is connected to a side surface of the first chip electrode 158 of the first light emitting diode Del1. The second connecting electrode 170 is disposed at a periphery of the second light emitting diode Del2 and is connected to a side surface of the first chip electrode of the second light emitting diode Del2. The second connecting electrode 170 is connected to the second reflecting electrode 154 through a contact hole in the adhesive layer 156 and is connected to the first reflecting electrode 152 through a contact hole in the adhesive layer 156.

The second planarizing layer 174 is disposed on the first and second light emitting diodes Del1 and Del2, the first, second and third connecting electrodes 168, 170 and 172 and the first bridge pattern Pbr1 over the entire substrate 130, and fourth and fifth connecting electrodes 176 and 178 are disposed on the second planarizing layer 174 corresponding to the first and second light emitting diodes Del1 and Del2. A capping pattern Pca is disposed on the second planarizing layer 174 corresponding to the first bridge pattern Pbr1.

The second planarizing layer 174 has the first contact hole Hco1 exposing the third connecting electrode 172, the second contact hole Hco2 exposing the first connecting electrode 168 and the first bridge hole Hbr1 exposing the first bridge pattern Pbr1.

The fourth connecting electrode 176 is connected to the third connecting electrode 172 through the first contact hole Hco1 and is connected to the second chip electrode 166 of the first light emitting diode Del1 exposed through the second planarizing layer 174. The fifth connecting electrode 178 is connected to the first connecting electrode 168 through the second contact hole Hco2 and is connected to the second chip electrode of the second light emitting diode Del2 exposed through the second planarizing layer 174. The fifth connecting electrode 178 has the second bridge hole Hbr2 exposing the first bridge hole Hbr1.

The capping pattern Pca is disposed in the second bridge hole Hbr2 of the fifth connecting electrode 178 and contacts the first bridge pattern Pbr1 through the first bridge hole Hbr1 of the second planarizing layer 174 to completely cover the first bridge pattern Pbr1 exposed through the first bridge hole Hbr1.

The first bridge pattern Pbr1 may have the same material in the same layer as the first, second and third connecting electrodes 168, 170 and 172, and the capping pattern Pca may have the same material in the same layer as the fourth and fifth connecting electrodes 176 and 178.

In the display device 110, the second connecting electrode 170 is connected to the first connecting electrode 168 through the first bridge pattern Pbr1, and the fifth connecting electrode 178 is connected to the first connecting electrode 168 through the second contact hole Hco2. Accordingly, the first and second chip electrodes 158 and 166 of the normal first light emitting diode Del1 are connected to the second and fourth connecting electrodes 170 and 176, respectively, and the first and second chip electrodes of the abnormal second light emitting diode Del2 are connected to the first connecting electrode 168 to be electrically shorted.

As a result, the first light emitting diode Del1 which operates normally may receive a hole from the driving transistor Tdr through the first reflecting electrode 152, the third connecting electrode 172 and the fourth connecting electrode 176 and may receive an electron from the low level power line 134 through the second reflecting electrode 154, the second connecting electrode 170, the first bridge pattern Pbr1 and the first connecting electrode 168 to emit a light.

In FIGS. 7 and 8, the light shielding pattern 132 and the low level power line 134, the buffer layer 136, the semiconductor layer 138, the gate insulating layer 140, the gate electrode 142, the interlayer insulating layer 144, the source electrode 146 and the drain electrode 148, the first planarizing layer 150, the first and second reflecting electrodes 152 and 154 and the adhesive layer 156 are sequentially disposed on the substrate 130.

The first and second light emitting diodes (chips) Del1 and Del2 spaced apart from each other and the first, second and third connecting electrodes 168, 170 and 172 spaced apart from each other are disposed in each of the first, second and third subpixels SP1, SP2 and SP3 on the adhesive layer 156.

Here, the first light emitting diode Del1 may be a light emitting diode chip which operates abnormally, and the second light emitting diode Del2 may be a light emitting diode chip which operates normally.

The first connecting electrode 168 is disposed at a periphery of the first light emitting diode Del1 and is connected to a side surface of the first chip electrode 158 of the first light emitting diode Del1. The second connecting electrode 170 is disposed at a periphery of the second light emitting diode Del2 and is connected to a side surface of the first chip electrode of the second light emitting diode Del2. The second connecting electrode 170 is connected to the second reflecting electrode 154 through a contact hole in the adhesive layer 156 and is connected to the first reflecting electrode 152 through a contact hole in the adhesive layer 156.

The second planarizing layer 174 is disposed on the first and second light emitting diodes Del1 and Del2 and the first, second and third connecting electrodes 168, 170 and 172 over the entire substrate 130, and fourth and fifth connecting electrodes 176 and 178 are disposed on the second planarizing layer 174 corresponding to the first and second light emitting diodes Del1 and Del2. A second bridge pattern Pbr2 is disposed on the second planarizing layer 174 between the fourth and fifth connecting electrodes 176 and 178.

The second planarizing layer 174 has the first contact hole Hco1 exposing the third connecting electrode 172, the second contact hole Hco2 exposing the first connecting electrode 168 and the first bridge hole Hbr1 exposing the adhesive layer 156 between the first and second connecting electrodes 168 and 170.

The fourth connecting electrode 176 is connected to the third connecting electrode 172 through the first contact hole Hco1 and is connected to the second chip electrode 166 of the first light emitting diode Del1 exposed through the second planarizing layer 174. The fifth connecting electrode 178 is connected to the first connecting electrode 168 through the second contact hole Hco2 and is connected to the second chip electrode of the second light emitting diode Del2 exposed through the second planarizing layer 174. The fifth connecting electrode 178 has the second bridge hole Hbr2 exposing the first bridge hole Hbr1.

The second bridge pattern Pbr2 may connect the fourth and fifth connecting electrodes 176 and 178 and may have the same material in the same layer as the fourth and fifth connecting electrodes 176 and 178.

In the display device 110, the fourth connecting electrode 176 is connected to the fifth connecting electrode 178 through the second bridge pattern Pbr2, and the fifth connecting electrode 178 is connected to the first connecting electrode 168 through the second contact hole Hco2. Accordingly, the first and second chip electrodes 158 and 166 of the abnormal first light emitting diode Del1 are connected to the first connecting electrode 168 to be electrically shorted, and the first and second chip electrodes of the normal second light emitting diode Del2 are connected to the second and fourth connecting electrodes 170 and 176, respectively.

As a result, the second light emitting diode Del2 which operates normally may receive a hole from the driving transistor Tdr through the first reflecting electrode 152, the third connecting electrode 172, the fourth connecting electrode 176, the second bridge pattern Pbr2 and the fifth connecting electrode 178 and may receive an electron from the low level power line 134 through the second reflecting electrode 154 and the second connecting electrode 170 to emit a light.

In the display device 110 according to a first embodiment of the present disclosure, when one of the first and second light emitting diodes Del1 and Del2 operates abnormally and the other of the first and second light emitting diodes Del1 and Del2 operates normally, the abnormal one is electrically shorted and the normal other is connected between the fourth connecting electrode 176 and the second connecting electrode 170 using the first bridge pattern Pbr1 or the second bridge pattern Pbr2. As a result, the abnormal subpixel is repaired.

In the display device 110 according to a first embodiment of the present disclosure, after the first and second light emitting diodes Del1 and Del2 are transferred to the substrate 130, it is detected whether the first and second light emitting diodes Del1 and Del2 operate normally or not by performing a lighting test using a probe. Further, it is determined whether the first bridge pattern Pbr1 is removed or not and it is determined whether the second bridge pattern Pbr2 and the capping pattern Pca are formed or not according to a result of the detection.

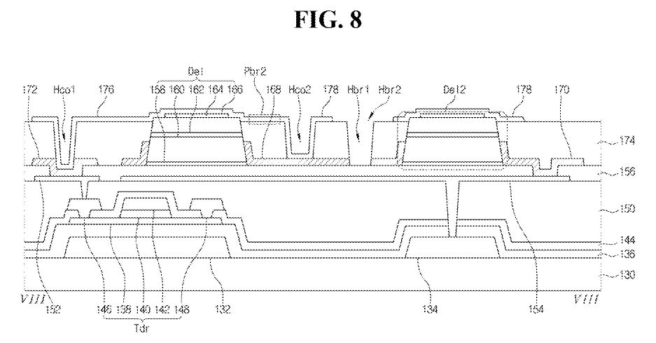

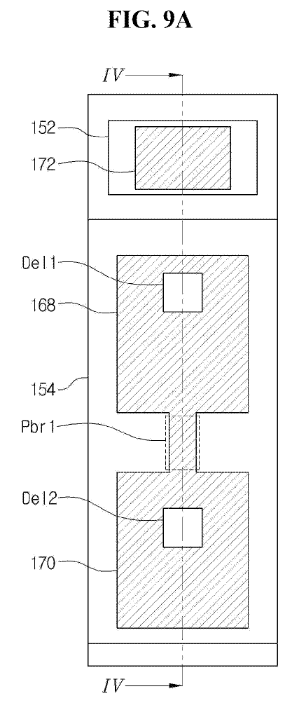

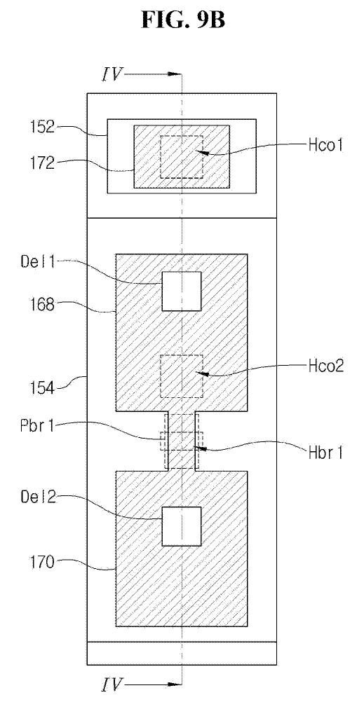

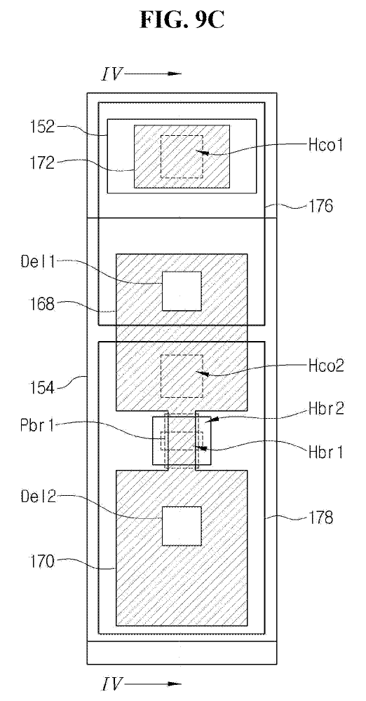

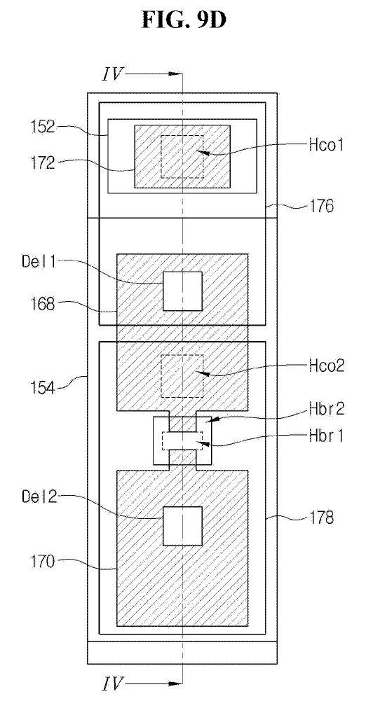

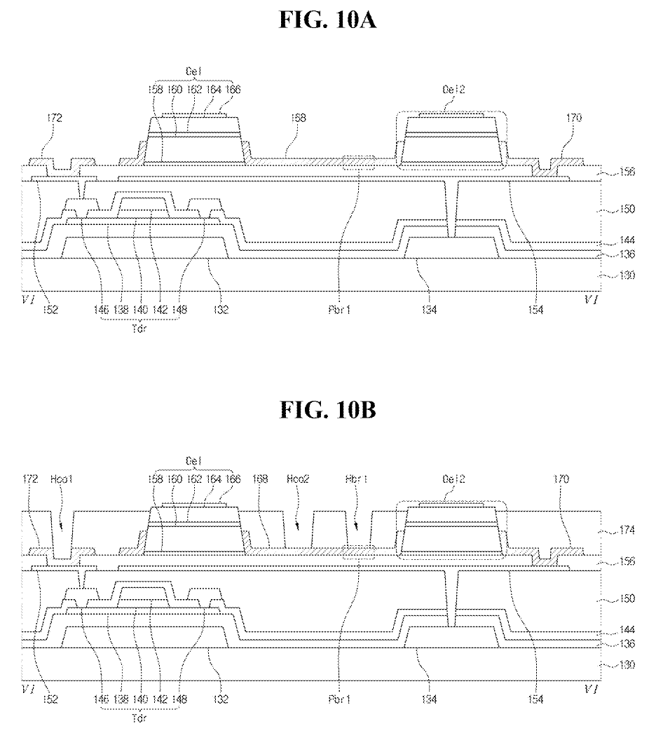

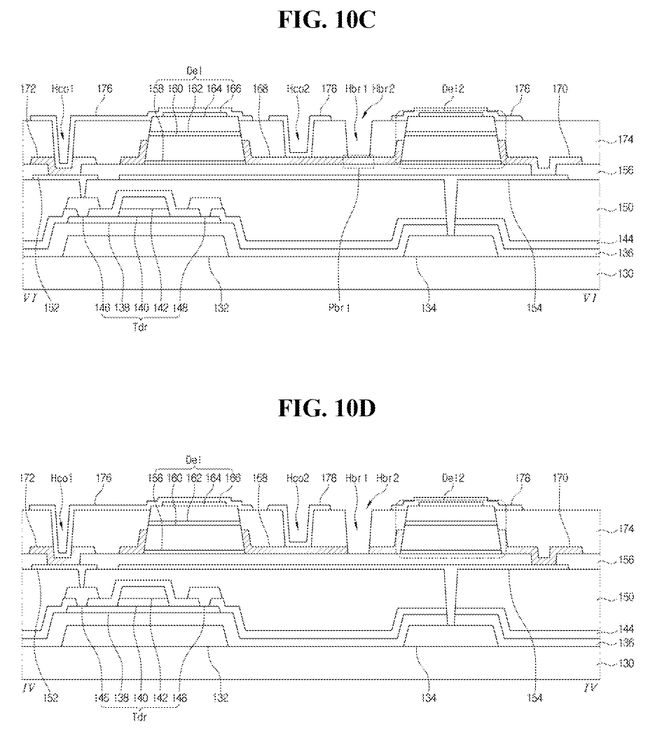

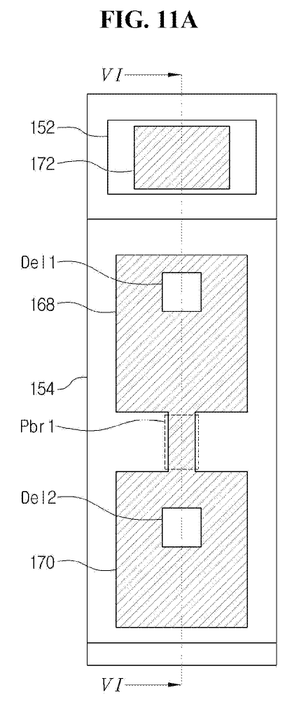

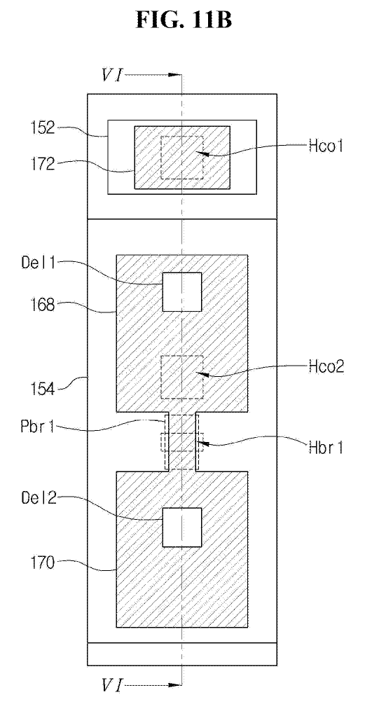

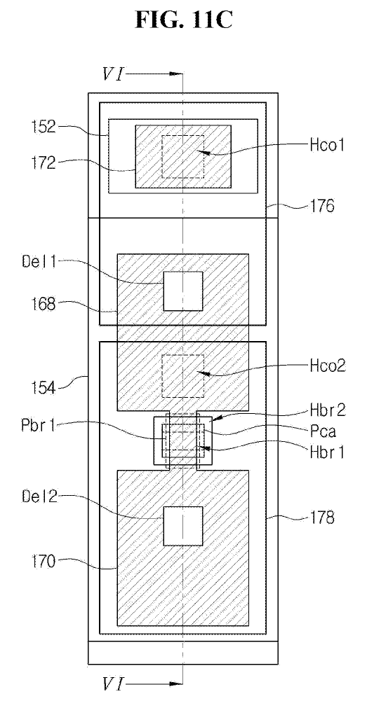

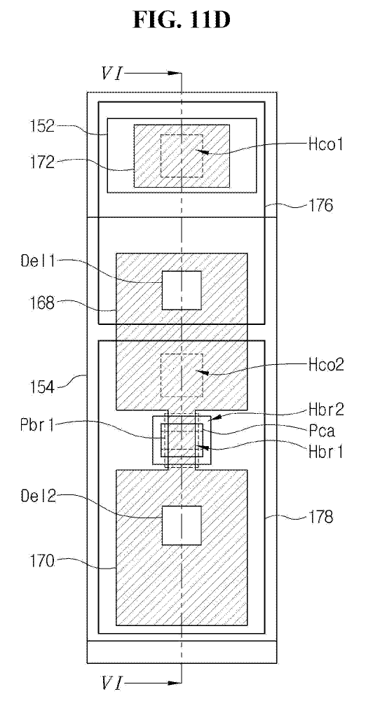

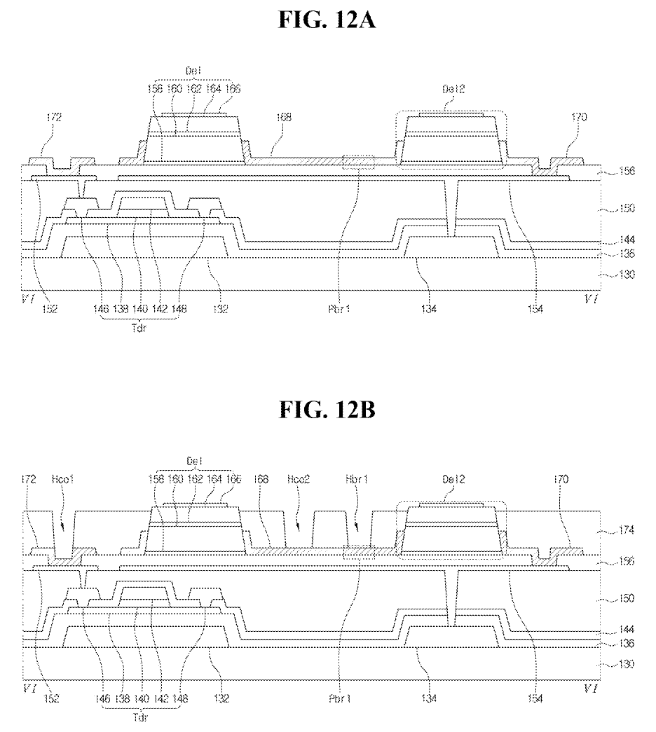

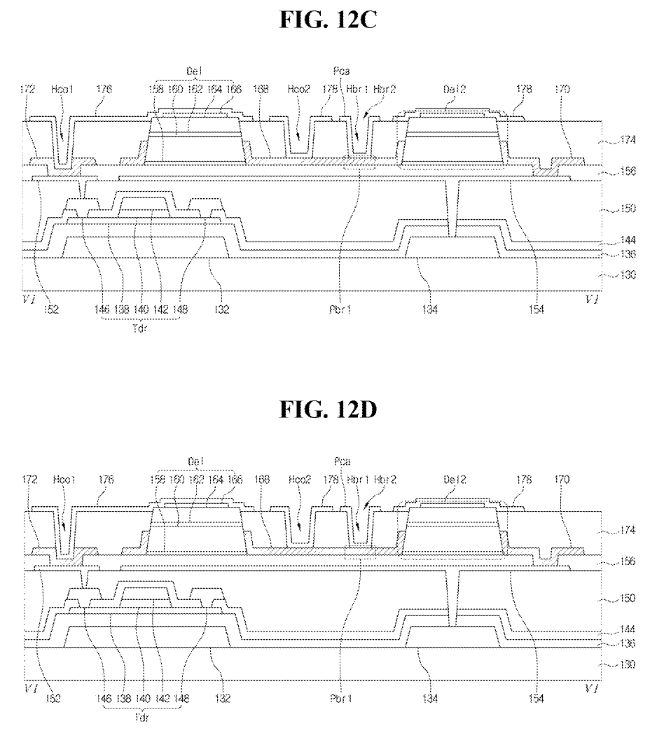

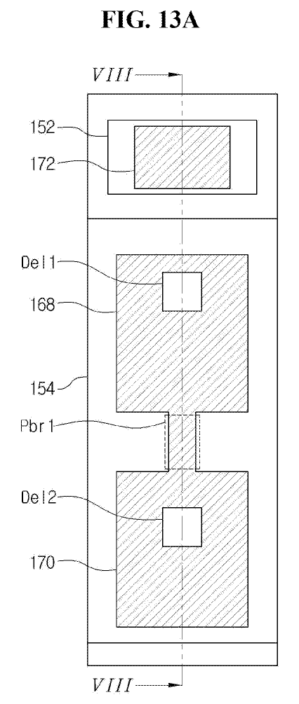

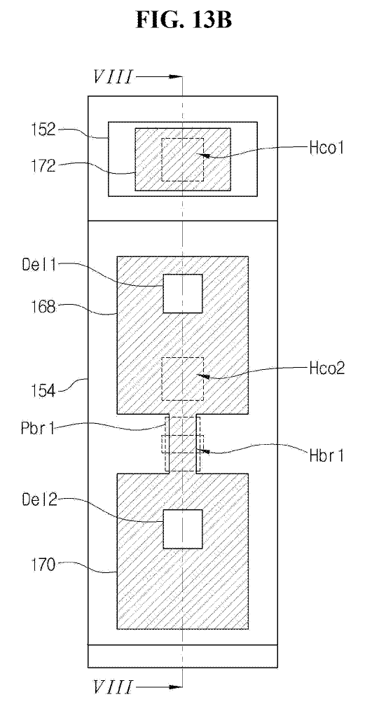

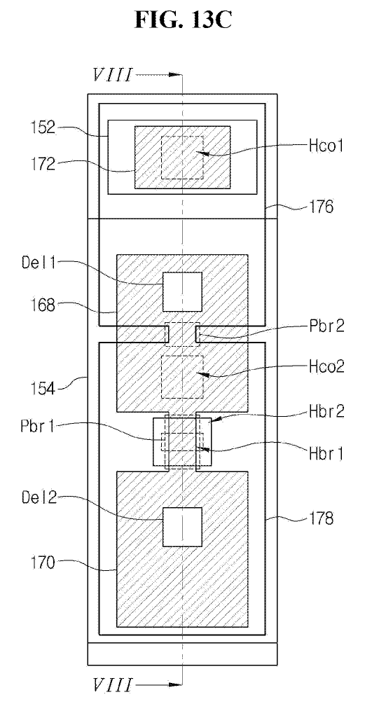

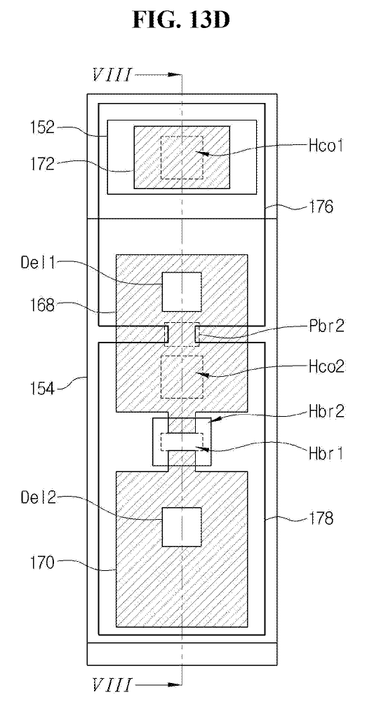

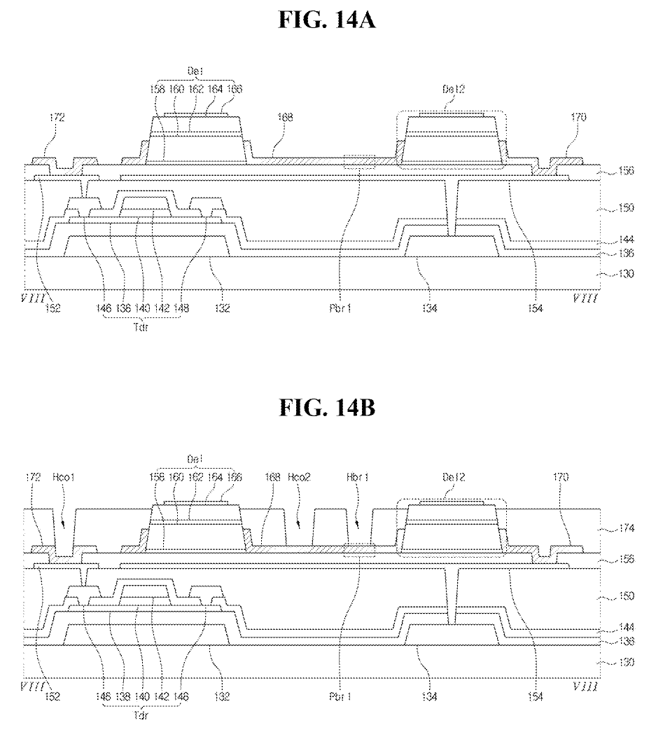

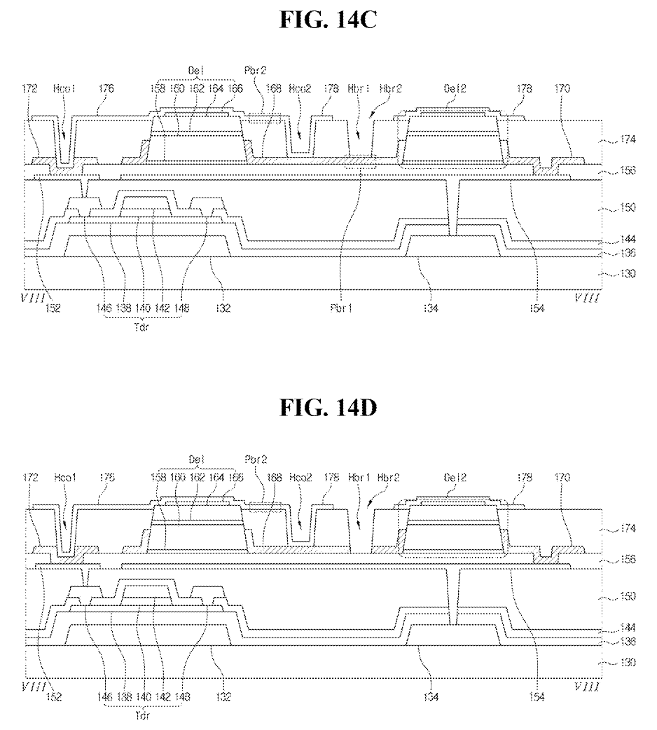

FIGS. 9A-9D are plan views showing a method of fabricating a subpixel having normal first and second light emitting diodes of a display panel of a display device according to a first embodiment of the present disclosure, and FIGS. 10A-10D are cross-sectional views showing a method of fabricating a subpixel having normal first and second light emitting diodes of a display panel of a display device according to a first embodiment of the present disclosure. FIGS. 11A-11D are plan views showing a method of fabricating a subpixel having a normal first light emitting diode and an abnormal second light emitting diode of a display panel of a display device according to a first embodiment of the present disclosure, and FIGS. 12A-12D are cross-sectional views showing a method of fabricating a subpixel having a normal first light emitting diode and an abnormal second light emitting diode of a display panel of a display device according to a first embodiment of the present disclosure. FIGS. 13A-13D are plan views showing a method of fabricating a subpixel having an abnormal first light emitting diode and a normal second light emitting diode of a display panel of a display device according to a first embodiment of the present disclosure, and FIGS. 14A-14D are cross-sectional views showing a method of fabricating a subpixel having an abnormal first light emitting diode and a normal second light emitting diode of a display panel of a display device according to a first embodiment of the present disclosure. Illustration on a part the same as that of FIGS. 3-8 may be omitted.

In FIGS. 9A and 10A for each subpixel SP1, SP2 and SP3 having the normal first and second light emitting diodes Del1 and Del2, FIGS. 11A and 12A for each subpixel SP1, SP2 and SP3 having the normal first light emitting diode Del1 and the abnormal second light emitting diode Del2, and FIGS. 13A and 14A for each subpixel SP1, SP2 and SP3 having the abnormal first light emitting diode Del1 and the normal second light emitting diode Del2, after the light shielding pattern 132 and the low level power line 134 are formed on the substrate 130, the buffer layer 136 is formed on the light shielding pattern 132 and the low level power line 134 over the entire substrate 130.

Next, after the semiconductor layer 138 is formed on the buffer layer 136 corresponding to the light shielding pattern 132, the gate insulating layer 140 is formed on the central portion of the semiconductor layer 138.

Next, after the gate electrode 142 is formed on the gate insulating layer 140 corresponding to the channel region of the semiconductor layer 138, the interlayer insulating layer 144 is formed on the gate electrode 142 over the entire substrate 130.

Next, after the source electrode 146 and the drain electrode 148 spaced apart from each other are formed on the interlayer insulating layer 144, the first planarizing layer 150 is formed on the source electrode 146 and the drain electrode 148 over the entire substrate 130.

Next, after the first and second reflecting electrodes 152 and 154 spaced apart from each other are formed on the first planarizing layer 150, the adhesive layer 156 is formed on the first and second reflecting electrodes 152 and 154 over the entire substrate 130.

Next, after the first and second light emitting diodes (chips) Del1 and Del2 are attached (transferred) to the adhesive layer 156 in each subpixel SP1, SP2 and SP3 to be spaced apart from each other, the first and second connecting electrodes 168 and 170, the first bridge pattern Pbr1 connecting the first and second connecting electrodes 168 and 170 and the third connecting electrode 172 spaced apart from the first connecting electrode 168 are formed on the adhesive layer 156.

Next, after voltages (e.g., low level signal Vss and high level signal Vdd) are supplied to the first and second chip electrodes 158 and 166 of the first and second light emitting diodes Del1 and Del2 in each subpixel SP1, SP2 and SP3, the lighting test where it is judged whether the first and second light emitting diodes Del1 and Del2 emit a light or not is performed.

Here, the first and second connecting electrodes 168 and 170 are connected to each other through the first bridge pattern Pbr1, and the first and second connecting electrodes 168 and 170 are connected to the first chip electrodes 158 of the first and second light emitting diodes Del1 and Del2, respectively. As a result, the low level signal Vss of the low level power line 134 may be applied to the first chip electrode of the second light emitting diode Del2 through the second reflecting electrode 154 and the second connecting electrode 170 and may be applied to the first chip electrode 158 of the first light emitting diode Del1 through the second reflecting electrode 154, the second connecting electrode 170, the first bridge pattern Pbr1 and the first connecting electrode 168.

Accordingly, it may be independently determined whether the first and second light emitting diodes Del1 and Del2 emit a light or not by contacting a probe to the second chip electrodes 166 of the first and second light emitting diodes Del1 and Del2 to apply the high level signal Vdd.

Next, a result of the lighting test including information of normal or abnormal operation of the first and second light emitting diodes Del1 and Del2 of each subpixel SP1, SP2 and SP3 is stored as a mapping data. The corresponding subpixel may be repaired by utilizing the mapping data for removal or remaining of the first bridge pattern Pbr1 and formation or omission of the second bridge pattern Pbr2 and the capping pattern Pca in a subsequent process.

In FIGS. 9B and 10B for each subpixel SP1, SP2 and SP3 having the normal first and second light emitting diodes Del1 and Del2, FIGS. 11B and 12B for each subpixel SP1, SP2 and SP3 having the normal first light emitting diode Del1 and the abnormal second light emitting diode Del2, and FIGS. 13B and 14B for each subpixel SP1, SP2 and SP3 having the abnormal first light emitting diode Del1 and the normal second light emitting diode Del2, the second planarizing layer 174 is formed on the first and second light emitting diodes Del1 and Del2, the first, second and third connecting electrodes 168, 170 and 172 and the first bridge pattern Pbr1 over the entire substrate 130.

The second planarizing layer 174 has the first contact hole Hco1 exposing the third connecting electrode 172, the second contact hole Hco2 exposing the first connecting electrode 168 and the first bridge hole Hbr1 exposing the first bridge pattern Pbr1, and a part of the second semiconductor layer 164 of each of the first and second light emitting diodes Del1 and Del2 and the second chip electrode 166 are exposed over the second planarizing layer 174.

In FIGS. 9C and 10C for each subpixel SP1, SP2 and SP3 having the normal first and second light emitting diodes Del1 and Del2, the fourth and fifth connecting electrodes 176 and 178 are formed on the second planarizing layer 174 corresponding to the first and second light emitting diodes Del1 and Del2, respectively.

The fourth connecting electrode 176 is connected to the third connecting electrode 172 through the first contact hole Hco1 and is connected to the second chip electrode 166 of the first light emitting diode Del1 exposed over the second planarizing layer 174. The fifth connecting electrode 178 is connected to the first connecting electrode 168 through the second contact hole Hco2 and is connected to the second chip electrode of the second light emitting diode Del2 exposed over the second planarizing layer 174. The fifth connecting electrode 178 has the second bridge hole Hbr2 exposing the first bridge hole Hbr1.

In FIGS. 11C and 12C for each subpixel SP1, SP2 and SP3 having the normal first light emitting diode Del1 and the abnormal second light emitting diode Del2, the fourth and fifth connecting electrodes 176 and 178 are formed on the second planarizing layer 174 corresponding to the first and second light emitting diodes Del1 and Del2, respectively, and the capping pattern Pca is formed on the second planarizing layer 174 corresponding to the first bridge pattern Pbr1.

The capping pattern Pca is disposed in the second bridge hole Hbr2 of the fifth connecting electrode 178 and contacts the first bridge pattern Pbr1 through the first bridge hole Hbr1 of the second planarizing layer 174 to completely cover the first bridge pattern Pbr1 exposed through the first bridge hole Hbr1.

For example, after a photoresist layer is patterned using a smart exposure apparatus where each subpixel may be exposed with an individual shape, a metallic material layer is patterned using a photoresist pattern as an etching mask to form the fourth and fifth connecting electrodes 176 and 178 and the capping pattern Pca.

In FIGS. 13C and 14C for each subpixel SP1, SP2 and SP3 having the abnormal first light emitting diode Del1 and the normal second light emitting diode Del2, the fourth and fifth connecting electrodes 176 and 178 are formed on the second planarizing layer 174 corresponding to the first and second light emitting diodes Del1 and Del2, respectively, and the second bridge pattern Pbr2 is formed on the second planarizing layer 174 between the fourth and fifth connecting electrodes 176 and 178.

The second bridge pattern Pbr2 connects the fourth and fifth connecting electrodes 176 and 178.

For example, after a photoresist layer is patterned using a smart exposure apparatus where each subpixel may be exposed with an individual shape, a metallic material layer is patterned using a photoresist pattern as an etching mask to form the fourth and fifth connecting electrodes 176 and 178 and the second bridge pattern Pbr2.

In FIGS. 9D and 10D for each subpixel SP1, SP2 and SP3 having the normal first and second light emitting diodes Del1 and Del2 and FIGS. 13D and 14D for each subpixel SP1, SP2 and SP3 having the abnormal first light emitting diode Del1 and the normal second light emitting diode Del2, the first bridge pattern Pbr1 exposed through the second bridge hole Hbr2 and the first bridge hole Hbr1 is removed through an etching process (e.g., wet etching).

As a result, the first and second connecting electrodes 168 and 170 are spaced apart from each other and are electrically separated.

In FIGS. 11D and 12D for each subpixel SP1, SP2 and SP3 having the normal first light emitting diode Del1 and the abnormal second light emitting diode Del2, since the first bridge pattern Pbr1 exposed through the second bridge hole Hbr2 and the first bridge hole Hbr1 is completely covered with the capping pattern Pca, the first bridge pattern Pbr1 is not removed and is protected by the capping pattern Pca during the etching process.

As a result, the first bridge pattern Pbr1 remains, and connection of the first and second connecting electrodes 168 and 170 through the first bridge pattern Pbr1 is maintained.

In the display device 110 according to a first embodiment of the present disclosure, the lighting test using a probe is performed in a state where the first and second light emitting diodes (chips) Del1 and Del2 are attached in each of the first, second and third subpixels SP1, SP2 and SP3 and the first bridge pattern Pbr1 connecting the first and second connecting electrodes 168 and 170 is formed. As a result, it may be independently determined whether each of the first and second light emitting diodes Del1 and Del2 emits a light or not.

Further, when the first and second light emitting diodes Del1 and Del2 operate normally, the first and second light emitting diodes Del1 and Del2 are connected in series between the fourth connecting electrode 176 and the second connecting electrode 170 using the first connecting electrode 168 and the fifth connecting electrode 178. As a result, a luminance may be improved and a power consumption may be reduced.

In addition, when one of the first and second light emitting diodes Del1 and Del2 operates normally and the other of the first and second light emitting diodes Del1 and Del2 operates abnormally, the abnormal one is electrically shorted and the normal other is connected between the fourth connecting electrode 176 and the second connecting electrode 170 using the first bridge pattern Pbr1 or the second bridge pattern Pbr2. As a result, the abnormal subpixel may be repaired.

In one or more other embodiments, the second bridge pattern Pbr2 and the capping pattern Pca may be formed in a single subpixel.

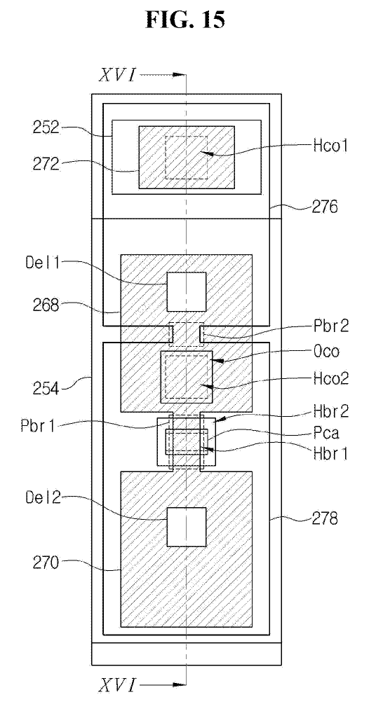

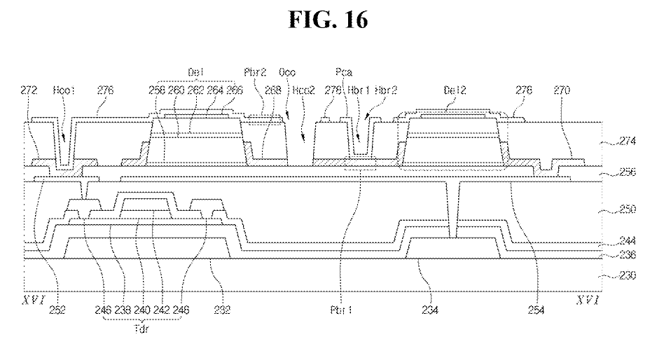

FIG. 15 is a plan view showing a subpixel having a normal light emitting diode and an abnormal light emitting diode of a display panel of a display device according to a second embodiment of the present disclosure, and FIG. 16 is a cross-sectional view taken along a line XVI-XVI of FIG. 15. Illustration on a part the same as that of a first embodiment may be omitted.

The subpixel having the first and second light emitting diodes which operate normally of the display panel of the display device according to a second embodiment of the present disclosure may have the same structure as the subpixel of FIGS. 3 and 4.

In FIGS. 15 and 16, a light shielding pattern 232 and a low level power line 234, a buffer layer 236, a semiconductor layer 238, a gate insulating layer 240, a gate electrode 242, an interlayer insulating layer 244, a source electrode 246 and a drain electrode 248, a first planarizing layer 250, first and second reflecting electrodes 252 and 254 and an adhesive layer 256 are sequentially disposed on a substrate 230.

First and second light emitting diodes (chips) Del1 and Del2 spaced apart from each other, first and second connecting electrodes 268 and 270, a first bridge pattern Pbr1 connecting the first and second connecting electrodes 268 and 270 and a third connecting electrode 272 spaced apart from the first connecting electrode 268 are disposed in each of first, second and third subpixels SP1, SP2 and SP3 on the adhesive layer 256.

Here, one of the first and second light emitting diodes Del1 and Del2 may be a light emitting diode chip which operates normally, and the other of the first and second light emitting diode Del1 and Del2 may be a light emitting diode chip which operates abnormally.

The first connecting electrode 268 is disposed at a periphery of the first light emitting diode Del1 and is connected to a side surface of a first chip electrode 258 of the first light emitting diode Del1. The second connecting electrode 270 is disposed at a periphery of the second light emitting diode Del2 and is connected to a side surface of the first chip electrode of the second light emitting diode Del2. The second connecting electrode 270 is connected to the second reflecting electrode 254 through a contact hole in the adhesive layer 256, and the third connecting electrode 272 is connected to the first reflecting electrode 252 through a contact hole in the adhesive layer 256.

A second planarizing layer 274 is disposed on the first and second light emitting diodes Del1 and Del2, the first, second and third connecting electrodes 268, 270 and 272 and the first bridge pattern Pbr1 over the entire substrate 230, and fourth and fifth connecting electrodes 276 and 278 are disposed on the second planarizing layer 274 corresponding to the first and second light emitting diodes Del1 and Del2. A second bridge pattern Pbr2 connecting the fourth and fifth connecting electrodes 276 and 278 is disposed on the second planarizing layer 274 between the fourth and fifth connecting electrodes 276 and 278.

The second planarizing layer 274 has a first contact hole Hco1 exposing the third connecting electrode 272, a second contact hole Hco2 exposing the adhesive layer 256 and a first bridge hole Hbr1 exposing the first bridge pattern Pbr1.

The fourth connecting electrode 276 is connected to the third connecting electrode 272 through the first contact hole Hco1 and is connected to a second chip electrode 266 of the first light emitting diode Del1 exposed over the second planarizing layer 274. The fifth connecting electrode 278 is connected to the second chip electrode of the second light emitting diode Del2 exposed over the second planarizing layer 274. The fifth connecting electrode 278 has a contact opening Oco exposing the second contact hole Hco2 and a second bridge hole Hbr2 exposing the first bridge hole Hbr1.

The fifth connecting electrode 278 is electrically separated from the first connecting electrode 268 due to the contact opening Oco where a part contacting the first connecting electrode 268 is removed.

A capping pattern Pca is disposed in the second bridge hole Hbr2 of the fifth connecting electrode 278 and contacts the first bridge pattern Pbr1 through the first bridge hole Hbr1 of the second planarizing layer 274 to completely cover the first bridge pattern Pbr1 exposed through the first bridge hole Hbr1.

The second bridge pattern Pbr2 connects the fourth and fifth connecting electrodes 276 and 278.

The first bridge pattern Pbr1 may have the same material in the same layer as the first, second and third connecting electrodes 268, 270 and 272, and the second bridge pattern Pbr2 and the capping pattern Pca may have the same material in the same layer as the fourth and fifth connecting electrodes 276 and 278.

In the subpixel of the display device where one of the first and second light emitting diodes Del1 and Del2 operates normally and the other of the first and second light emitting diodes Del1 and Del2 operates abnormally, the first and second connecting electrodes 268 and 270 are connected to each other through the first bridge pattern Pbr1, the fourth and fifth connecting electrodes 276 and 278 are connected to each other through the second bridge pattern Pbr2, and the first and fifth connecting electrodes 268 and 278 are separated from each other due to the contact opening Oco. Accordingly, the first and second chip electrodes 258 and 266 of the first and second light emitting diodes Del1 and Del2 are connected to the second and fourth connecting electrodes 270 and 276, respectively, and the first and second light emitting diodes Del1 and Del2 are connected in parallel between the second and fourth connecting electrodes 270 and 276.

As a result, in the subpixel having the normal first light emitting diode Del1 and the abnormal second light emitting diode Del2, the normal first light emitting diode Del1 may receive a hole from the driving transistor Tdr through the first reflecting electrode 252, the third connecting electrode 272 and the fourth connecting electrode 276 and may receive an electron from the low level power line 234 through the second reflecting electrode 254, the second connecting electrode 270, the first bridge pattern Pbr1 and the first connecting electrode 268 to emit a light.

Further, in the subpixel having the abnormal first light emitting diode Del1 and the normal second light emitting diode Del2, the normal second light emitting diode Del2 may receive a hole from the driving transistor Tdr through the first reflecting electrode 252, the third connecting electrode 272, the fourth connecting electrode 276, the second bridge pattern Pbr2 and the fifth connecting electrode 278 and may receive an electron from the low level power line 234 through the second reflecting electrode 254 and the second connecting electrode 270 to emit a light.

In the display device according to a second embodiment of the present disclosure, when one of the first and second light emitting diodes Del1 and Del2 operates normally and the other of the first and second light emitting diodes Del1 and Del2 operates abnormally, the abnormal subpixel having the abnormal light emitting diode may be repaired by connecting the normal light emitting diode between the fourth connecting electrode 176 and the second connecting electrode 270 using the first bridge pattern Pbr1 or the second bridge pattern Pbr2.

In the display device according to a second embodiment of the present disclosure, after the first and second light emitting diodes Del1 and Del2 are transferred to the substrate 230, it is detected whether the first and second light emitting diodes Del1 and Del2 operate normally or not by performing a lighting test using a probe. Further, it is determined whether the first bridge pattern Pbr1 is removed or not and it is determined whether the second bridge pattern Pbr2 and the capping pattern Pca are formed or not according to a result of the detection.

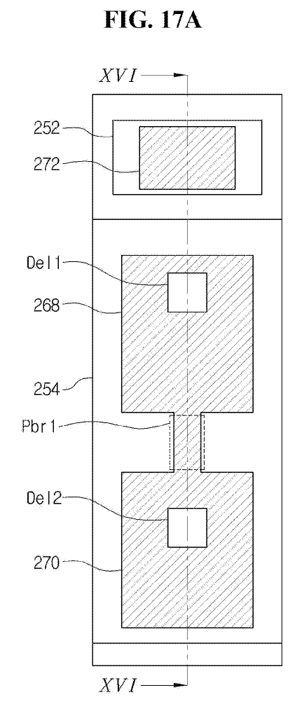

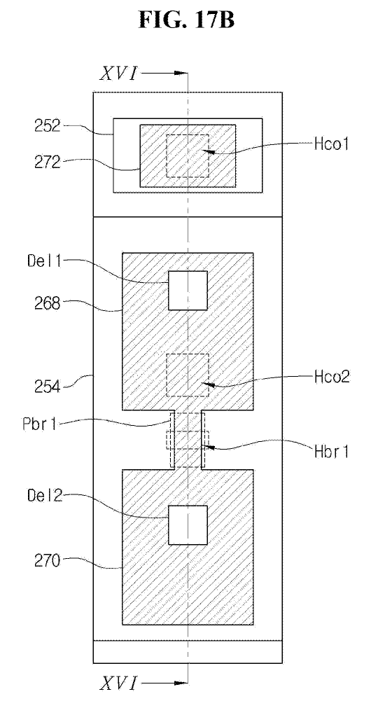

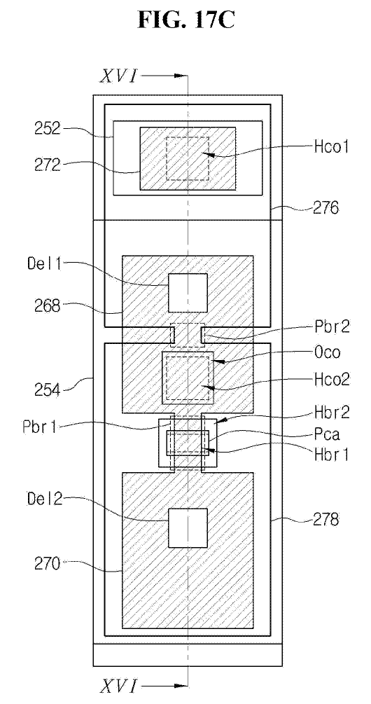

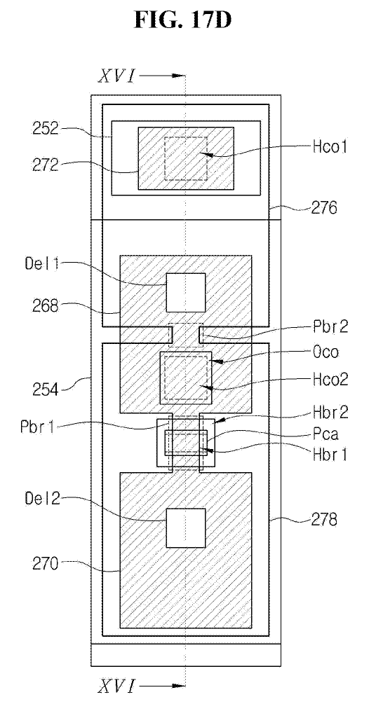

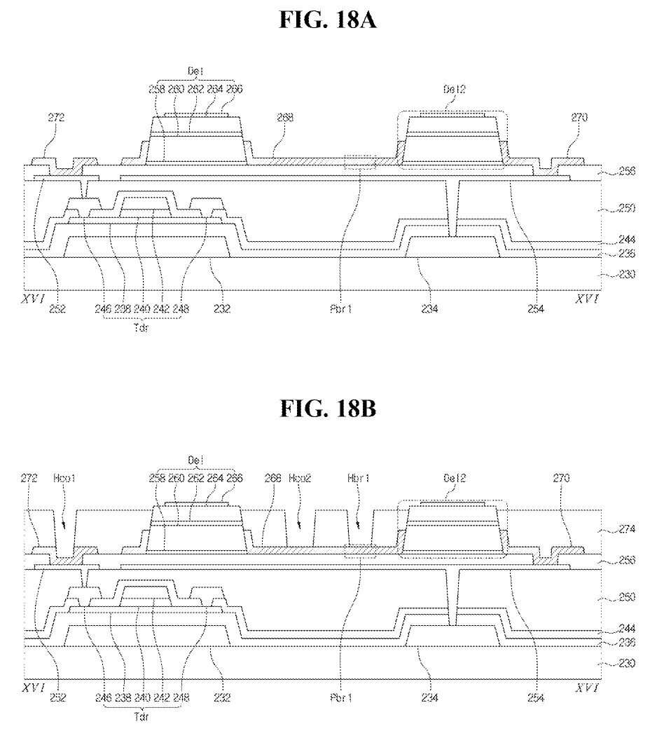

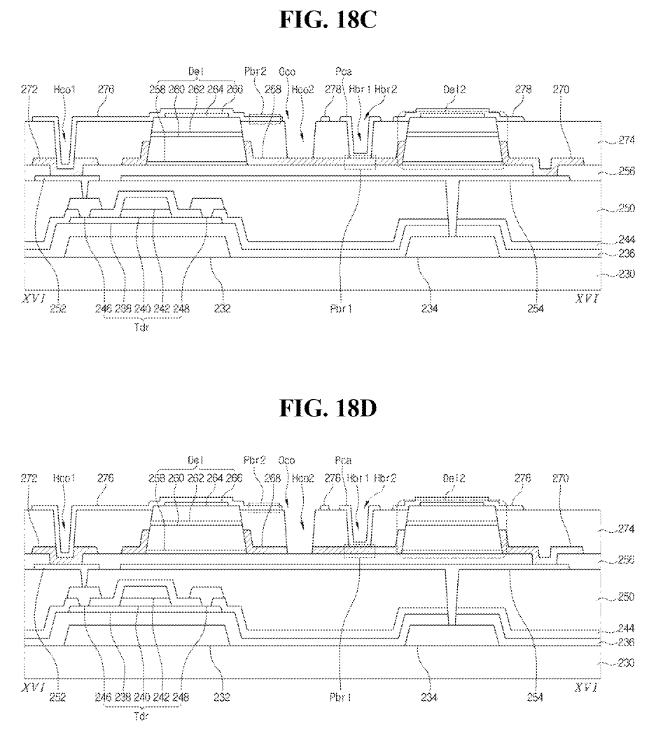

FIGS. 17A-17D are plan views showing a method of fabricating a subpixel having a normal light emitting diode and an abnormal light emitting diode of a display panel of a display device according to a second embodiment of the present disclosure, and FIGS. 18A-18D are cross-sectional views showing a method of fabricating a subpixel having a normal light emitting diode and an abnormal light emitting diode of a display panel of a display device according to a second embodiment of the present disclosure. Illustration on a part the same as that of FIGS. 15-16 may be omitted.

The method of fabricating the subpixel having the first and second light emitting diodes which operate normally of the display panel of the display device according to a second embodiment of the present disclosure may have the same steps as the method of fabricating the subpixel of FIGS. 9A-9D and 10A-10D.

In FIGS. 17A and 18A for each subpixel SP1, SP2 and SP3 where one of the first and second light emitting diodes Del1 and Del2 operates normally and the other of the first and second light emitting diodes Del1 and Del2 operates abnormally, after the light shielding pattern 232 and the low level power line 234 are formed on the substrate 230, the buffer layer 236 is formed on the light shielding pattern 232 and the low level power line 234 over the entire substrate 230.

Next, after the semiconductor layer 238 is formed on the buffer layer 236 corresponding to the light shielding pattern 232, the gate insulating layer 240 is formed on the central portion of the semiconductor layer 238.

Next, after the gate electrode 242 is formed on the gate insulating layer 240 corresponding to the channel region of the semiconductor layer 238, the interlayer insulating layer 244 is formed on the gate electrode 242 over the entire substrate 230.

Next, after the source electrode 246 and the drain electrode 248 spaced apart from each other are formed on the interlayer insulating layer 244, the first planarizing layer 250 is formed on the source electrode 246 and the drain electrode 248 over the entire substrate 230.

Next, after the first and second reflecting electrodes 252 and 254 spaced apart from each other are formed on the first planarizing layer 250, the adhesive layer 256 is formed on the first and second reflecting electrodes 252 and 254 over the entire substrate 230.

Next, after the first and second light emitting diodes (chips) Del1 and Del2 are attached (transferred) to the adhesive layer 256 in each subpixel SP1, SP2 and SP3 to be spaced apart from each other, the first and second connecting electrodes 268 and 270, the first bridge pattern Pbr1 connecting the first and second connecting electrodes 268 and 270 and the third connecting electrode 272 spaced apart from the first connecting electrode 268 are formed on the adhesive layer 256.

Next, after voltages (e.g., low level signal Vss and high level signal Vdd) are supplied to the first and second chip electrodes 258 and 266 of the first and second light emitting diodes Del1 and Del2 in each subpixel SP1, SP2 and SP3, the lighting test where it is judged whether the first and second light emitting diodes Del1 and Del2 emit a light or not is performed.

Here, the first and second connecting electrodes 268 and 270 are connected to each other through the first bridge pattern Pbr1, and the first and second connecting electrodes 268 and 270 are connected to the first chip electrodes 258 of the first and second light emitting diodes Del1 and Del2, respectively. As a result, the low level signal Vss of the low level power line 134 may be applied to the first chip electrode of the second light emitting diode Del2 through the second reflecting electrode 254 and the second connecting electrode 270 and may be applied to the first chip electrode 258 of the first light emitting diode Del1 through the second reflecting electrode 254, the second connecting electrode 270, the first bridge pattern Pbr1 and the first connecting electrode 268.

Accordingly, it may be independently determined whether the first and second light emitting diodes Del1 and Del2 emit a light or not by contacting a probe to the second chip electrodes 266 of the first and second light emitting diodes Del1 and Del2 to apply the high level signal Vdd.

Next, a result of the lighting test including information of normal or abnormal operation of the first and second light emitting diodes Del1 and Del2 of each subpixel SP1, SP2 and SP3 is stored as a mapping data. The corresponding subpixel may be repaired by utilizing the mapping data for removal or remaining of the first bridge pattern Pbr1 and formation or omission of the second bridge pattern Pbr2 and the capping pattern Pca in a subsequent process.

In FIGS. 17B and 18B for each subpixel SP1, SP2 and SP3 where one of the first and second light emitting diodes Del1 and Del2 operates normally and the other of the first and second light emitting diodes Del1 and Del2 operates abnormally, the second planarizing layer 274 is formed on the first and second light emitting diodes Del1 and Del2, the first, second and third connecting electrodes 268, 270 and 272 and the first bridge pattern Pbr1 over the entire substrate 230.

The second planarizing layer 274 has the first contact hole Hco1 exposing the third connecting electrode 272, the second contact hole Hco2 exposing the first connecting electrode 268 and the first bridge hole Hbr1 exposing the first bridge pattern Pbr1, and a part of the second semiconductor layer 264 of each of the first and second light emitting diodes Del1 and Del2 and the second chip electrode 266 are exposed over the second planarizing layer 274.

In FIGS. 17C and 18C for each subpixel SP1, SP2 and SP3 where one of the first and second light emitting diodes Del1 and Del2 operates normally and the other of the first and second light emitting diodes Del1 and Del2 operates abnormally, the fourth and fifth connecting electrodes 276 and 278 are formed on the second planarizing layer 274 corresponding to the first and second light emitting diodes Del1 and Del2, respectively, the capping pattern Pca is formed on the second planarizing layer 274 corresponding to the first bridge pattern Pbr1, and the second bridge pattern Pbr2 is formed on the second planarizing layer 274 between the fourth and fifth connecting electrodes 276 and 278.

The capping pattern Pca is disposed in the second bridge hole Hbr2 of the fifth connecting electrode 278 and contacts the first bridge pattern Pbr1 through the first bridge hole Hbr1 of the second planarizing layer 274 to completely cover the first bridge pattern Pbr1 exposed through the first bridge hole Hbr1.

The second bridge pattern Pbr2 connects the fourth and fifth connecting electrodes 276 and 278.

For example, after a photoresist layer is patterned using a smart exposure apparatus where each subpixel may be exposed with an individual shape, a metallic material layer is patterned using a photoresist pattern as an etching mask to form the fourth and fifth connecting electrodes 276 and 278, the capping pattern Pca and the second bridge pattern Pbr2.

In FIGS. 17D and 18D for each subpixel SP1, SP2 and SP3 where one of the first and second light emitting diodes Del1 and Del2 operates normally and the other of the first and second light emitting diodes Del1 and Del2 operates abnormally, a part of the first connecting electrode 268 exposed through the contact opening Oco and the second contact hole Hco2 is removed through an etching process (e.g., wet etching).

Since the first bridge pattern Pbr1 exposed through the second bridge hole Hbr2 and the first bridge hole Hbr1 is completely covered with the capping pattern Pca, the first bridge pattern Pbr1 is not removed and is protected by the capping pattern Pca during the etching process.

As a result, the first bridge pattern Pbr1 remains, and connection of the first and second connecting electrodes 268 and 270 through the first bridge pattern Pbr1 is maintained.

In the display device according to a second embodiment of the present disclosure, the lighting test using a probe is performed in a state where the first and second light emitting diodes (chips) Del1 and Del2 are attached in each of the first, second and third subpixels SP1, SP2 and SP3 and the first bridge pattern Pbr1 connecting the first and second connecting electrodes 268 and 270 is formed. As a result, it may be independently determined whether each of the first and second light emitting diodes Del1 and Del2 emits a light or not.

Further, when the first and second light emitting diodes Del1 and Del2 operate normally, the first and second light emitting diodes Del1 and Del2 are connected in series between the fourth connecting electrode 276 and the second connecting electrode 270 using the first connecting electrode 268 and the fifth connecting electrode 278. As a result, a luminance may be improved and a power consumption may be reduced.

In addition, when one of the first and second light emitting diodes Del1 and Del2 operates normally and the other of the first and second light emitting diodes Del1 and Del2 operates abnormally, the first and second light emitting diodes Del1 and Del2 are connected in parallel between the fourth connecting electrode 276 and the second connecting electrode 270 using the first bridge pattern Pbr1 or the second bridge pattern Pbr2. As a result, the abnormal subpixel may be repaired.

It will be apparent to those skilled in the art that various modifications and variation may be made in the present disclosure without departing from the scope of the disclosure. Thus, it is intended that the present disclosure cover the modifications and variations of this disclosure provided they come within the scope of the appended claims and their equivalents.

What is claimed is:

1. A display device, comprising:
a substrate;
a low level power line on the substrate;
a transistor on the substrate;
a first planarizing layer on the transistor;
first and second reflecting electrodes on the first planarizing layer, the first and second reflecting electrodes spaced apart from each other and connected to the transistor and the low level power line, respectively;
an adhesive layer on the first and second reflecting electrodes;
first and second light emitting diodes on the adhesive layer, the first and second light emitting diodes spaced apart from each other;
first, second and third connecting electrodes on the adhesive layer, the second connecting electrode connected to the second reflecting electrode, and the third connecting electrode spaced apart from the first connecting electrode and connected to the first reflecting electrode;
a second planarizing layer on the first and second light emitting diodes and on the first, second and third connecting electrodes; and
fourth and fifth connecting electrodes on the second planarizing layer, the fourth and fifth connecting electrodes spaced apart from each other and connected to the first and second light emitting diodes, respectively.

2. The display device of claim 1, wherein the second planarizing layer has a first contact hole exposing the third connecting electrode, a second contact hole exposing the first connecting electrode and a first bridge hole exposing the adhesive layer between the first and second connecting electrodes,
wherein the fourth connecting electrode is connected to the third connecting electrode through the first contact hole, and
wherein the fifth connecting electrode is connected to the first connecting electrode through the second contact hole and has a second bridge hole exposing the first bridge hole.

3. The display device of claim 1, wherein the substrate has a first subpixel where the first and second light emitting diodes operate normally, a second subpixel where the first light emitting diode operates normally and the second light emitting diode operates abnormally, and a third subpixel where the first light emitting diode operates abnormally and the second light emitting diode operates normally, and
wherein a first bridge pattern connecting the first and second connecting electrodes is disposed on the adhesive layer, and
wherein a capping pattern is disposed on the second planarizing layer corresponding to the first bridge pattern in the second subpixel.

4. The display device of claim 3, wherein a second bridge pattern connecting the fourth and fifth connecting electrodes is disposed on the second planarizing layer in the third subpixel.

5. The display device of claim 1, wherein each of the first and second light emitting diodes comprises:
a first chip electrode on the adhesive layer;
a first chip semiconductor layer on the first chip electrode;
a chip active layer on the first chip semiconductor layer;
a second chip semiconductor layer on the chip active layer; and
a second chip electrode on the second chip semiconductor layer.

6. The display device of claim 5, wherein the first connecting electrode is connected to a side surface of the first chip electrode of the first light emitting diode,
wherein the second connecting electrode is connected to a side surface of the first chip electrode of the second light emitting diode,
wherein the fourth connecting electrode is connected to the second chip electrode of the first light emitting diode exposed over the second planarizing layer, and
wherein the fifth connecting electrode is connected to the second chip electrode of the second light emitting diode exposed over the second planarizing layer.

7. A method of fabricating a display device, comprising:
forming a low level power line on a substrate;
forming a transistor on the low level power line;
forming a first planarizing layer on the transistor;
forming first and second reflecting electrodes on the first planarizing layer, the first and second reflecting electrodes spaced apart from each other and connected to the transistor and the low level power line, respectively;
forming an adhesive layer on the first and second reflecting electrodes;
forming first and second light emitting diodes on the adhesive layer, the first and second light emitting diodes spaced apart from each other;
forming first, second and third connecting electrodes and a first bridge pattern on the adhesive layer, the second connecting electrode connected to the second reflecting electrode, the third connecting electrode spaced apart from the first connecting electrode and connected to the first reflecting electrode, and the first bridge pattern connecting the first and second connecting electrodes;
forming a second planarizing layer on the first and second light emitting diodes, the first, second and third connecting electrodes and the first bridge pattern; and
forming fourth and fifth connecting electrodes on the second planarizing layer, the fourth and fifth connecting electrodes connected to the first and second light emitting diodes, respectively.

8. The method of claim 7, further comprising performing a lighting test for each of the first and second light emitting diodes by applying a low level signal of the low level power line to the first and second connecting electrodes and the first bridge pattern between a step of forming the first, second and third connecting electrodes and the first bridge pattern and a step of forming the second planarizing layer.

9. The method of claim 7, wherein the substrate has a first subpixel where the first and second light emitting diodes operate normally, a second subpixel where the first light emitting diode operates normally and the second light emitting diode operates abnormally, and a third subpixel where the first light emitting diode operates abnormally and the second light emitting diode operates normally.

10. The method of claim 9, further comprising removing the first bridge pattern in the first subpixel.

11. The method of claim 10, further comprising forming a capping pattern on the second planarizing layer corresponding to the first bridge pattern in the second subpixel.

12. The method of claim 11, further comprising forming a second bridge pattern connecting the fourth and fifth connecting electrodes on the second planarizing layer in the third subpixel.

13. A display device, comprising:
a substrate;
a first planarizing layer disposed on the substrate;
a first reflective electrode and a second reflective electrode disposed on the first planarizing layer and spaced apart from each other in a plan view;
an adhesive layer disposed on the first planarizing layer and cover the first reflective electrode and the second reflective electrode;
a first light emitting diode and a second light emitting diode disposed on the adhesive layer and spaced apart from each other in the plan view;
a first connection electrode, a second connection electrode, and a third connection electrode disposed on the adhesive layer, the second connection electrode being electrically connected to the second reflective electrode, and the third connection electrode being spaced apart from the first connection electrode and electrically connected to the first reflective electrode;
a second planarizing layer disposed over the first light emitting diode, the second light emitting diode, the first connection electrode, the second connection electrode, and the third connection electrode; and
a fourth connection electrode and a fifth connection electrode disposed on the second planarizing layer and spaced apart from each other, the fourth connection electrode being electrically connected to the first light emitting diode, and the fifth connection electrode being electrically connected to the second light emitting diode.
